(19) United States
(12) Patent Application Publication
(10) Pub. No.: US 2025/0158303 A1
(43) Pub. Date: May 15, 2025

(54) POWER CONNECTOR COMBINED WITH INSERTION PINS

(71) Applicant: JESS-LINK PRODUCTS CO., LTD., New Taipei City (TW)

(72) Inventors: Hsu-Feng CHANG, New Taipei City (TW); Lin HUANG, Guiping City (CN)

(21) Appl. No.: 18/616,345

(22) Filed: Mar. 26, 2024

(30) Foreign Application Priority Data
Nov. 9, 2023 (CN) 202323032171.6
Nov. 13, 2023 (TW) 112143692

(51) Int. Cl. H01R 12/72

(52) U.S. Cl. CPC H01R 12/724

(57) ABSTRACT

A power connector is provided, used with a circuit board having conductive holes. The power connector includes an insulating housing and a power terminal group. One end of the insulating housing includes two strip-shaped openings arranged side by side, and the other end includes multiple sockets. A portion of the sockets are arranged in a column aligned with one strip-shaped opening, and the rest of the sockets are arranged in a column aligned with the other strip-shaped opening. Both a positive terminal and a negative terminal of the power terminal group have a conductive plate, with multiple insertion pins extending from one end of the conductive plate, and at least one conductive pin extending from the other end. Each conductive plate is inserted into each strip-shaped opening, each insertion pin is inserted into each socket, and each conductive pin is inserted into each conductive hole.

### BACKGROUND OF THE INVENTION

### Technical Field

The present disclosure relates to a power connector, and in particular to a power connector combined with insertion pins.

### Description of Related Art

Power connectors are conductive electronic components used to connect electrical circuits. They are widely used in various electrical circuits to connect or disconnect circuits, or to provide power connections between different circuit systems or devices.

However, as connectors evolve towards simpler structures and better transmission performance, the focus for power connector manufacturers has become how to integrate multiple interfaces and pins and enhance the current-carrying efficiency of the power connectors.

In view of this, the inventor has devoted himself to research on the above-mentioned existing technology and cooperated with the application of academic theory to try his best to solve the above-mentioned problems, which has become the development goal of the inventor.

### SUMMARY OF THE INVENTION

The disclosure provides a power connector combined with multiple insertion pins. It utilizes multiple insertion pins and conductive pins of both a positive terminal and a negative terminal, extending from a single conductive plate, to achieve desirable current-carrying efficiency in this power connector.

In one embodiment of the present disclosure, a power connector combined with insertion pins is provided for use with a circuit board with several conductive holes. The power connector includes: an insulating housing, one end of the insulating housing including at least one pair of strip-shaped openings arranged side by side and another end of the insulating housing including a plurality of sockets, wherein a part of the sockets are arranged in a column parallelly corresponding to one of the strip-shaped openings, and the rest of the sockets are arranged in a column parallelly corresponding to the other one of the strip-shaped openings; and at least one power terminal group including a positive terminal and a negative terminal, wherein each of the positive terminal and the negative terminal includes a conductive plate, multiple ones of the insertion pins extend from one end of each of the conductive plates, at least one conductive pin extends from another end of each of the conductive plates, the conductive plates is respectively inserted into the strip-shaped openings, and each of the insertion pins is inserted into a respective corresponding one of the sockets, and each of the conductive pins is inserted into a respective corresponding one of the conductive holes.

Consequently, the multiple insertion pins and conductive pins of both the positive and negative terminals receive power from a single conductive plate. Simultaneously, a cross-sectional area of the conductive plate increases, allowing the power connector of this disclosure to withstand larger currents and achieve better effects when temperature rises, thereby ensuring excellent current-carrying efficiency.

### BRIEF DESCRIPTION OF THE DRAWINGS

FIG. 1 is an exploded perspective view of a power connector according to a first embodiment of the present disclosure.

FIG. 2 is a schematic view of a usage state of the power connector according to the first embodiment of the present disclosure.

FIG. 3 is a schematic view of another usage state of the power connector according to the first embodiment of the present disclosure.

FIG. 4 is a schematic view of a usage state of the power connector according to a second embodiment of the present disclosure.

FIG. 5 is a schematic view of another usage state of the power connector according to the second embodiment of the present disclosure.

FIG. 6 is a schematic view of a usage state of the power connector according to a third embodiment of the present disclosure.

FIG. 7 is a schematic view of another usage state of the power connector according to the third embodiment of the present disclosure.

FIG. 8 is a schematic view of a usage state of the power connector according to a fourth embodiment of the present disclosure.

FIG. 9 is a schematic view of another usage state of the power connector according to the fourth embodiment of the present disclosure.

FIG. 10 is a schematic view of a usage state of the power connector according to a fifth embodiment of the present disclosure.

FIG. 11 is a schematic view of another usage state of the power connector according to the fifth embodiment of the present disclosure.

FIG. 12 is a schematic view of a usage state of the power connector according to a sixth embodiment of the present disclosure.

FIG. 13 is a schematic view of another usage state of the power connector according to the sixth embodiment of the present disclosure.

FIG. 14 is a schematic view of a usage state of the power connector according to a seventh embodiment of the present disclosure.

FIG. 15 is a schematic view of another usage state of the power connector according to the seventh embodiment of the present disclosure.

### DETAILED DESCRIPTION

The detailed description and technical content of the present disclosure will be described below with reference to the drawings. However, the attached drawings are only for illustrative purposes and are not intended to limit the present disclosure.

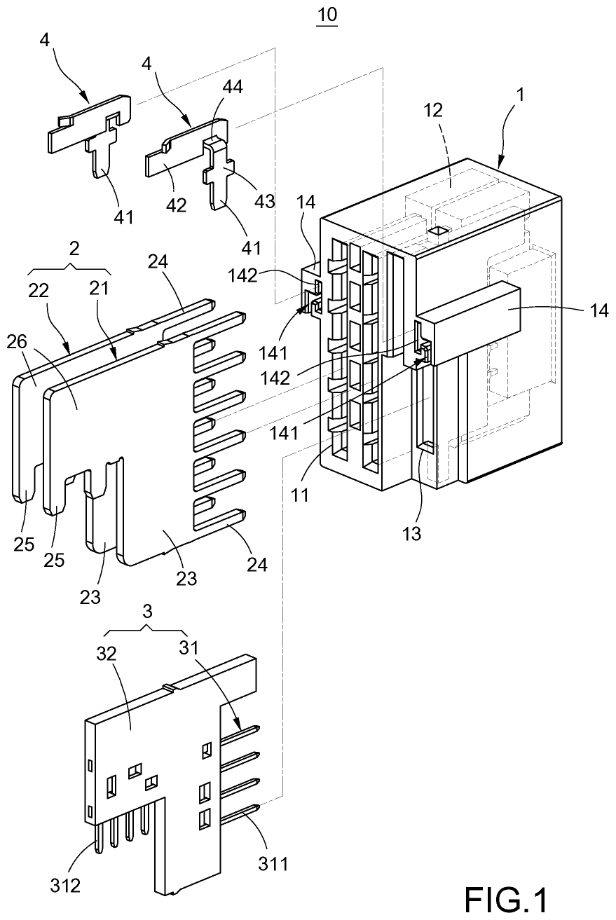

Referring to FIGS. 1 to 3, this disclosure provides a power connector combined with insertion pins for use with a circuit board 100. The circuit board 100 has a hollowed-out port 101, multiple conductive holes 102 arranged around the hollowed-out port 101, and two fixing holes 103. The power connector 10 mainly includes an insulating housing 1 and a power terminal group 2. As shown in FIGS. 1 to 3, the power connector 10 is a Mini-Fit connector. One end of the insulating housing 1 is provided with a pair of strip-shaped openings 11 arranged side by side, and the other end of the insulating housing 1 is provided with multiple sockets 12. A portion of these sockets 12 is arranged in a column parallelly corresponding to one of the strip-shaped openings 11, and the rest of the sockets 12 is arranged in a column parallelly corresponding to the other strip-shaped opening 11, forming the two columns of sockets 12 arranged side by side. Also, the insulating housing 1 is provided with a strip-shaped through hole 13 arranged alongside the strip-shaped openings 11.

In this embodiment, the insulating housing 1 is embedded in the hollowed-out port 101, making the power connector 10 a sinking-board type connector. However, the present disclosure is not limited in this regard, as the power connector 10 may also be a board-mounted connector.

Additionally, the insulating housing 1 has two protrusions 14 extended from two sides thereof and located at two sides of the strip-shaped openings 11. Each protrusion 14 is provided with a slot 141, which is an H-shaped groove 142 opened from one side wall of each protrusion 14, but the present disclosure is not limited in this regard.

As shown in FIGS. 1 to 3, the power terminal group 2 includes a positive terminal 21 and a negative terminal 22. The positive terminal 21 and the negative terminal 22 respectively have a conductive plate 23, multiple insertion pins 24 extending from one end of the conductive plate 23 in the same plane as the conductive plate 23 and one or more conductive pins 25 extending from another end of the conductive plate 23. Each conductive plate 23 is inserted into the respective strip-shaped opening 11, and each insertion pin 24 is inserted into the respective socket 12, so that the power terminal group 2 is installed inside the insulating housing 1. The conductive pins 25 are inserted into a portion of the conductive holes 102, electrically connecting the power terminal group 2 with the circuit board 100.

Furthermore, each conductive plate 23 extends with an extension sheet 26 located between the conductive plate 23 and the conductive pin 25 and exposed from the insulating housing 1.

In this embodiment, the strip-shaped openings 11 are vertically arranged side by side, and there are multiple conductive plates 23 for both the positive terminal 21 and the negative terminal 22. Each conductive plate 23 is arranged perpendicularly to the circuit board 100. Each conductive pin 25 and the corresponding extension sheet 26 are in the same plane. Each extension sheet 26 and the corresponding conductive plate 23 are in the same plane.

As shown in FIGS. 1 to 3, the power connector 10 of the present disclosure further includes a signal terminal group 3. The signal terminal group 3 includes multiple signal terminals 31 and an insulating sheet 32 covering a middle section of the signal terminals 31. The insulating sheet 32 is inserted into the strip-shaped through hole 13. Each signal terminal 31 has one end with a first pin 311 arranged parallel to each insertion pin 24 and accommodated in the strip-shaped through hole 13, and has another end with a second pin 312 arranged parallel to each conductive pin 25 and inserted into another portion of the conductive holes 102, thus electrically connecting the signal terminals 31 with the circuit board 100.

The power connector 10 of this disclosure also includes two fixing plates 4. Each fixing plate 4 is inserted into each slot 141. Each fixing plate 4 has a fixing pin 41 exposed outside each protrusion 14 and inserted into each fixing hole 103, securing the power connector 10 to the circuit board 100.

Further details are as follows: each fixing plate 4 includes an I-shaped piece 42, a cross-shaped piece 43, and a connecting piece 44 integrally connected between the I-shaped piece 42 and the cross-shaped piece 43. Upper sections of each I-shaped piece 42, each connecting piece 44, and each cross-shaped piece 43 are inserted into the respective H-shaped groove 142, and each cross-shaped piece 43 is engaged with the respective protrusion 14. Each fixing pin 41 extends from a bottom end of each cross-shaped piece 43.

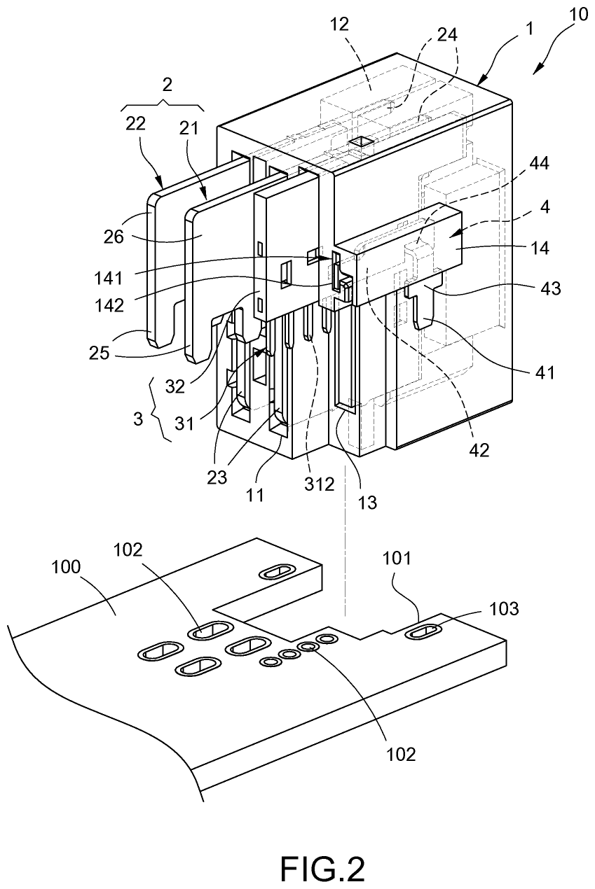

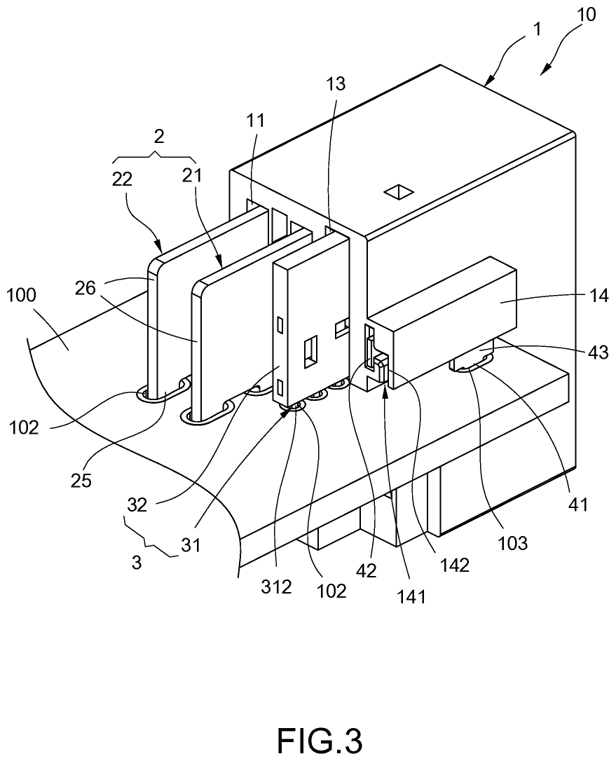

As shown in FIGS. 2 and 3, in the use state of the power connector 10 of the present disclosure, the insertion pins 24 and the conductive pin 25 of both the positive terminal 21 and the negative terminal 22 extend from a single conductive plate 23. The insertion pins 24 and the conductive pin 25 receive power from the single conductive plate 23, while a cross-sectional area of the conductive plate 23 is increased, allowing the power connector 10 to withstand larger currents and may better alleviate temperature rise issues, achieving excellent current-carrying efficiency.

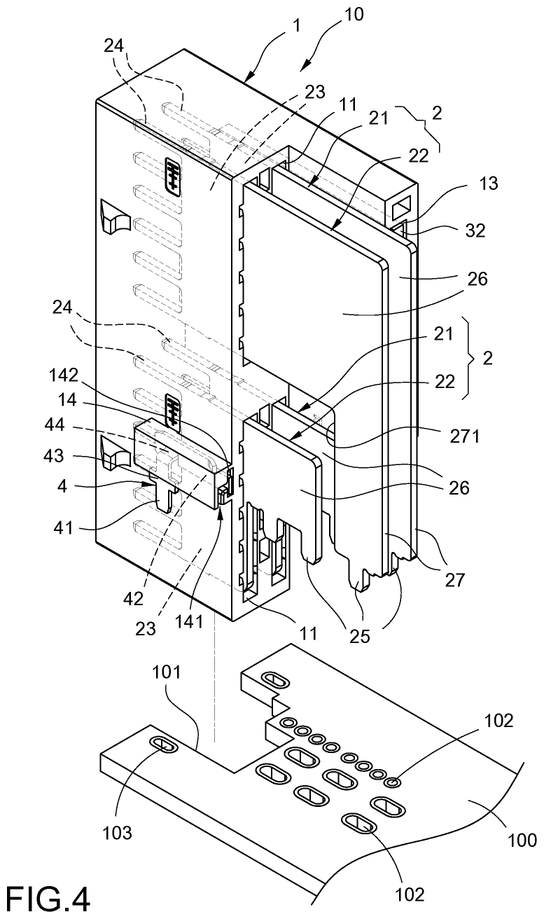

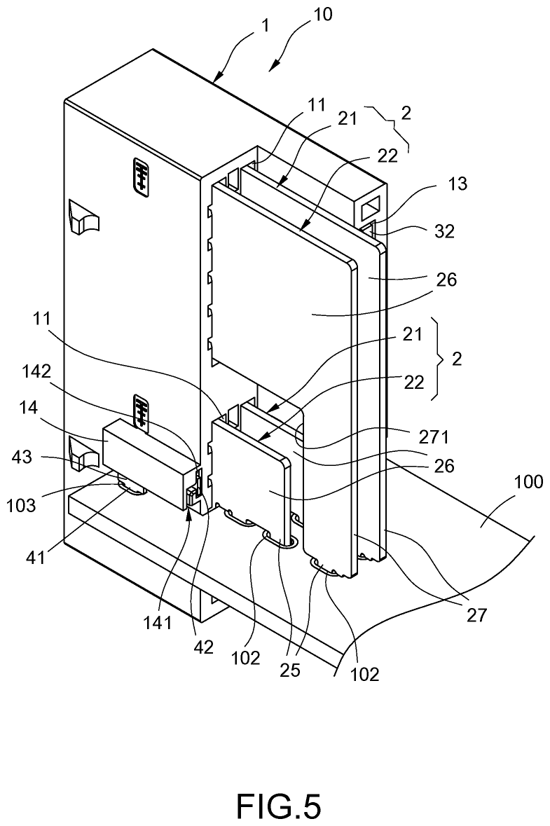

Please refer to FIG. 4 to FIG. 5, which is a second embodiment of the power connector 10 of the present disclosure. The embodiment of FIG. 4 to FIG. 5 is substantially the same as the embodiment of FIG. 1 to FIG. 3. The embodiment of FIG. 4 to FIG. 5 is different from the embodiment of FIGS. 1 to 3 in that the number of the strip-shaped openings 11 is two pairs and the number of the power terminal groups 2 is two.

Further explanations are as follows: in this embodiment, each conductive plate 23 is arranged perpendicularly to the circuit board 100, the two pairs of strip-shaped openings 11 are arranged one above the other. The extension sheets 26 of the power terminal group 2 inserted in the upper strip-shaped openings 11 are L-shaped pieces 27. Each L-shaped pieces 27 and the respective conductive plate 23 are positioned in the same plane. Each L-shaped piece 27 has a gap 271 formed in its shape. The extension sheets 26 of the power terminal group 2 inserted in the lower strip-shaped openings 11 are accommodated within the gaps 271 of the L-shaped pieces 27. Thus, the power connector 10 of the present embodiment has two power terminal groups 2 arranged above and below.

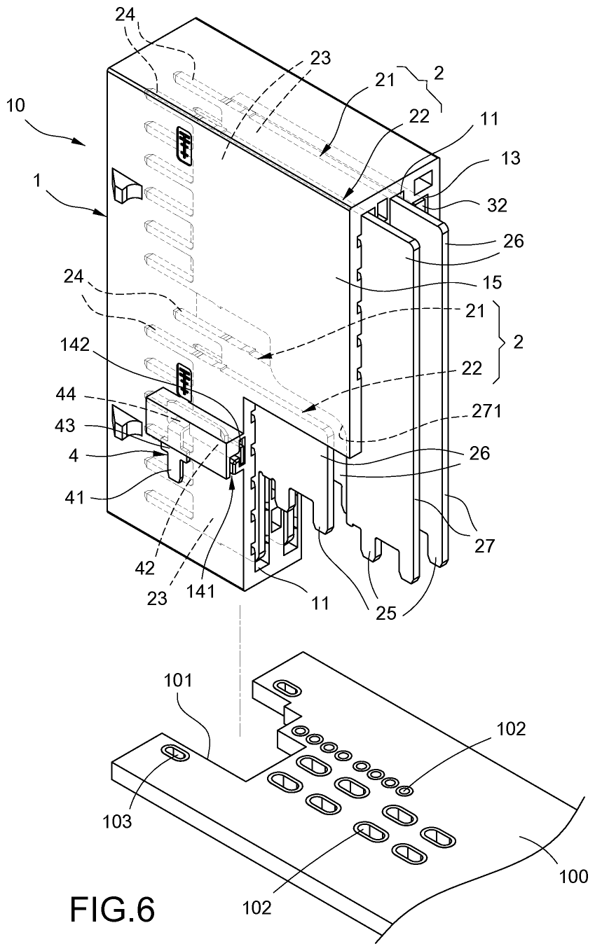

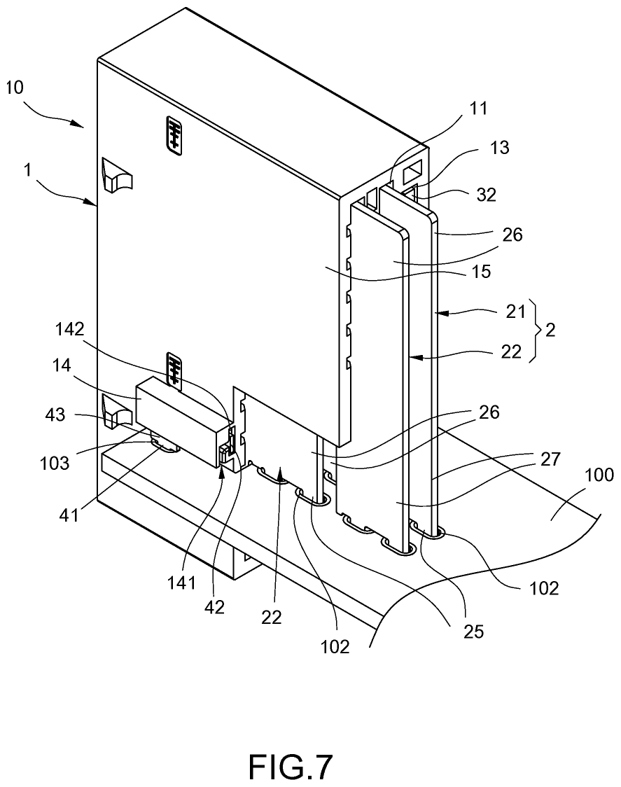

Please refer to FIGS. 6 to 7, which show a third embodiment of the power connector 10 of the present disclosure. The embodiment shown in FIGS. 6 to 7 is similar to the embodiment in FIGS. 4 to 5, with the difference being that a rear end of the insulating housing 1 extends with a cover section 15. The cover section 15 shields the front sections of the L-shaped pieces 27, protecting the front sections of the L-shaped pieces 27.

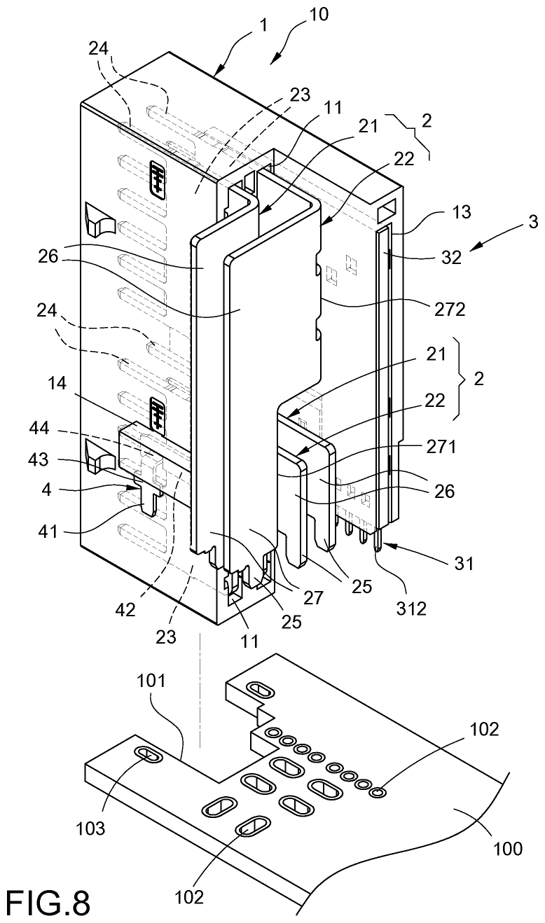

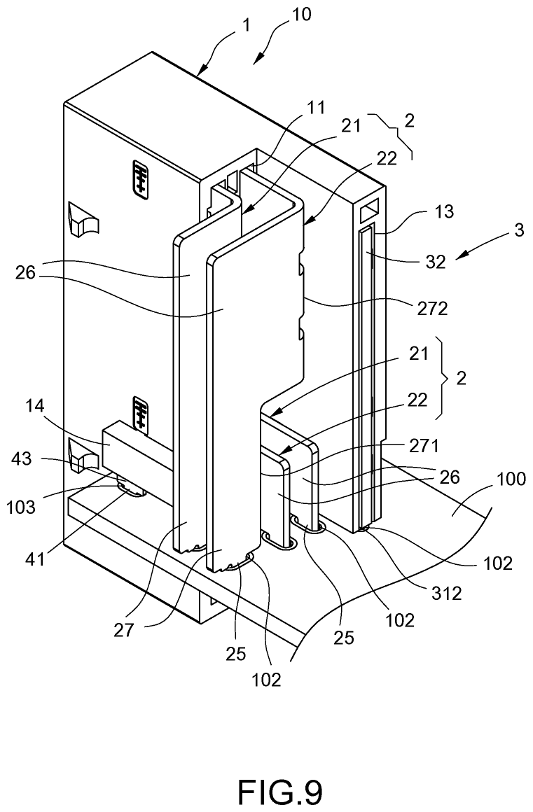

Please refer to FIGS. 8 to 9, which show a fourth embodiment of the power connector 10 of the present disclosure. The embodiment shown in FIGS. 8 to 9 is similar to the embodiment in FIGS. 4 to 5, with the difference being that the shape of the L-shaped pieces 27 is different. In this embodiment, each L-shaped piece 27 has a bending section 272, thus positioning the front section of each L-shaped piece 27 in the same plane as the respective conductive plate 23. The rear section of each L-shaped piece 27 is arranged perpendicularly to the respective conductive plate 23 and positioned on one side of the respective extension sheet 26 of the lower power terminal group 2. Thus, because the rear sections of the L-shaped pieces 27 of this embodiment are bent and positioned on one side of the extension sheets 26 of the lower power terminal group 2, the power connector 10 in FIGS. 8 to 9 is thinner in length compared to the power connector 10 in FIGS. 4 to 5.

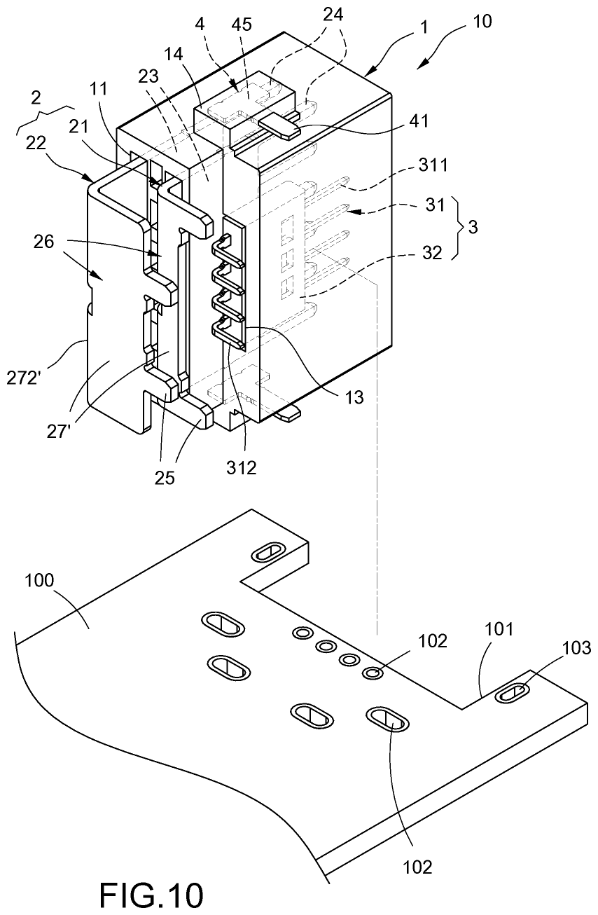

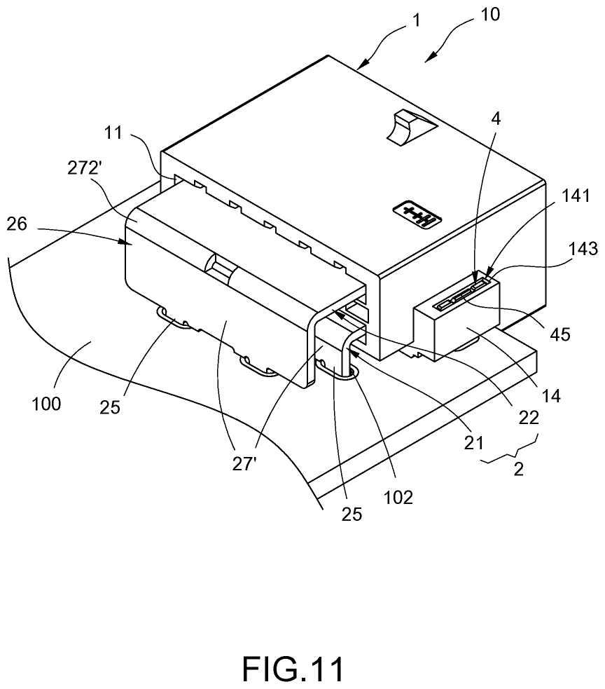

Refer to FIGS. 10 to 11, which show a fifth embodiment of the power connector 10 of the present disclosure. The embodiment shown in FIGS. 10 to 11 is similar to the embodiment in FIGS. 1 to 3, with the difference being that the pair of strip-shaped openings 11 are horizontally arranged one above the other, and the slots 141 and the protrusions 14 are different in shape.

Further detailed descriptions are as follows: in this embodiment, the pair of strip-shaped openings 11 are horizontally arranged one above the other. Each conductive plate 23 is arranged parallel to the circuit board 100, and each conductive plate 23 and the respective extension sheet 26 are arranged perpendicularly to each other. Each extension sheet 26 is bent into an L-shaped piece 27′, and each L-shaped piece 27′ has a bending section 272′, positioning the front sections of the L-shaped pieces 27′ in the same plane as the respective conductive plates 23, and the rear sections of the L-shaped pieces 27′ are arranged perpendicularly to the respective conductive plates 23. One of the L-shaped pieces 27′ accommodated below the other L-shaped piece 27′. Additionally, each slot 141 is a T-shaped channel 143 opened from a top of each protrusion 14, and each fixing plate 4 is a T-shaped piece 45. Each T-shaped piece 45 is inserted into each T-shaped channel 143 and engages with the respective protrusion 14. Each fixing pin 41 extends from a bottom end of each T-shaped piece 45, and the fixing pin 41 is inserted into the fixing hole 103, thus fixing the power connector 10 to the circuit board 100.

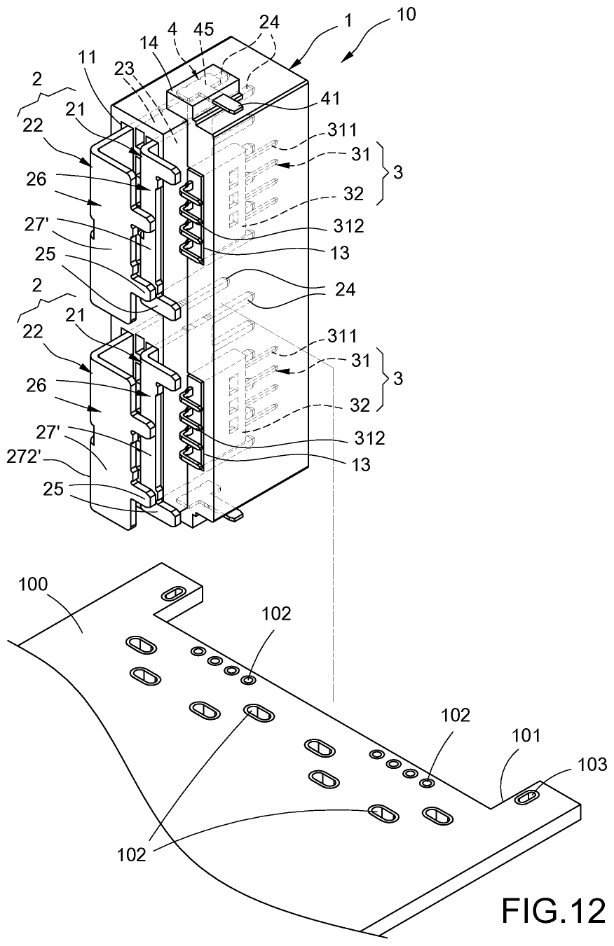

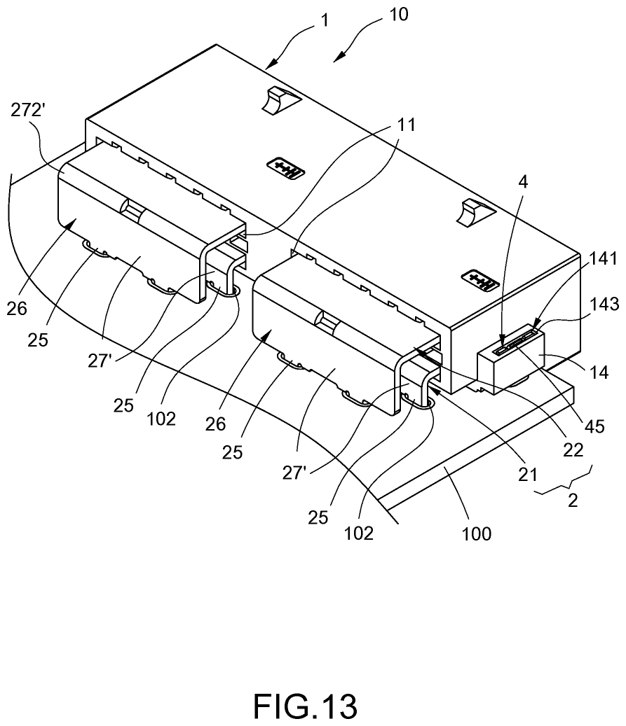

Refer to FIGS. 12 to 13, which show a sixth embodiment of the power connector 10 of the present disclosure. The embodiment shown in FIGS. 12 to 13 is similar to the embodiment in FIGS. 10 to 11, with the difference being that the number of the strip-shaped openings 11 is two pairs and the number of the power terminal groups 2 is two. The two pairs of strip-shaped openings 11 and the two power terminal groups 2 are arranged left and right. Thus, the power connector 10 of this embodiment has two power terminal groups 2 arranged side by side, positioned left and right.

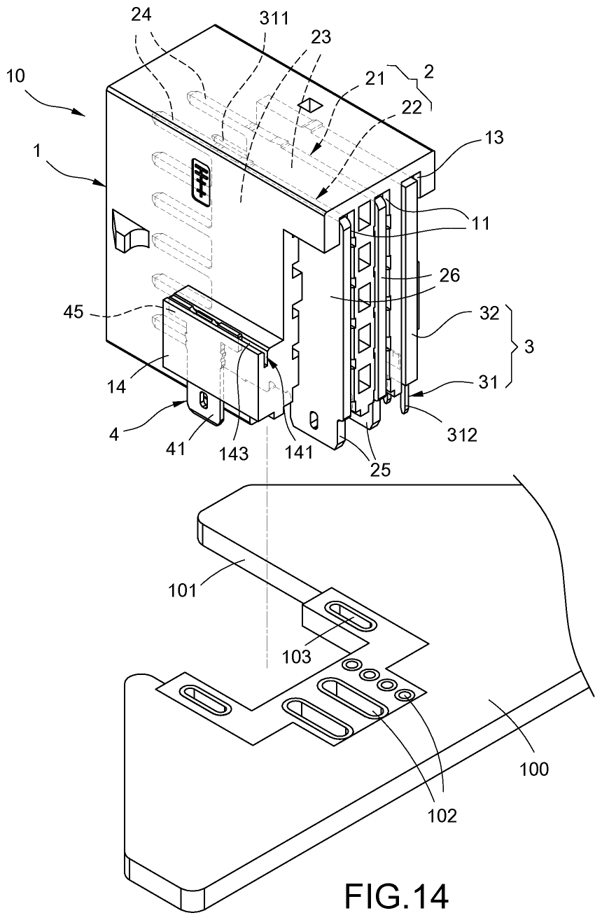

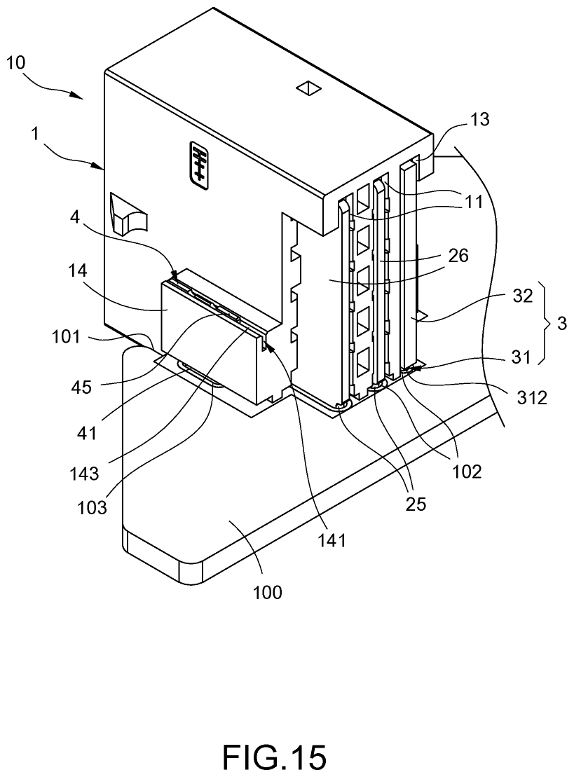

Refer to FIGS. 14 to 15, which show a seventh embodiment of the power connector 10 of the present disclosure. The embodiment shown in FIGS. 14 to 15 is similar to the embodiment in FIGS. 1 to 3, with the difference being that the number of the conductive plates 23 for the positive terminal 21 and the negative terminal 22 is one each, and the slots 141 and the protrusions 14 are of a different shape.

Further detailed descriptions are as follows: in this embodiment, the number of the conductive plates 23 for the positive terminal 21 and the negative terminal 22 is one each. Each conductive plate 23 is arranged perpendicularly to the circuit board 100, and each conductive pin 25 and the respective extension sheet 26 are positioned in the same plane. Each extension sheet 26 and the respective conductive plate 23 are in the same plane. The conductive pins 25 are inserted into some of the conductive holes 102, so as to electrically connect the power terminal group 2 with the circuit board 100. Thus, this achieves the same functionality and effectiveness as the embodiment shown in FIGS. 1 to 3.

Additionally, in this embodiment, the shape of the slots 141 and the protrusions 14 is similar to those in FIGS. 10 to 11. Each slot 141 is a T-shaped channel 143 opened from a top of each protrusion 14, and each fixing plate 4 is a T-shaped piece 45. Each T-shaped piece 45 is inserted into each T-shaped channel 143 and engages with each protrusion 14. Each fixing pin 41 extends from a bottom end of each T-shaped piece 45, with the fixing pin 41 inserted into the fixing hole 103, thus fixing the power connector 10 to the circuit board 100.

In summary, in the present disclosure, the power connector combined with the insertion pins has not been seen in similar products or publicly used.

What is claimed is:

1. A power connector, used with a circuit board, the circuit board comprising a plurality of conductive holes, the power connector comprising:
an insulating housing, comprising at least one pair of strip-shaped openings defined side by side on one end thereof and a plurality of sockets defined on another end thereof, wherein a part of the sockets is arranged parallelly in a column corresponding to one of the strip-shaped openings, and another part of the sockets are arranged parallelly in a column corresponding to another one of the strip-shaped openings; and
at least one power terminal group, comprising a positive terminal and a negative terminal, wherein each of the positive terminal and the negative terminal comprises a conductive plate, a plurality of insertion pins extended from one end of the conductive plate, and at least one conductive pin extended from another end of the conductive plate, wherein two conductive plates are respectively inserted in the strip-shaped openings, and each of the insertion pins is inserted in each of the sockets, and the conductive pin is inserted in one of the conductive holes.

2. The power connector according to claim 1, wherein the conductive plate comprises an extension sheet extended from the another end thereof, the extension sheet is disposed between the conductive plate and the conductive pin and exposed from the insulating housing, and each of the conductive pins and the extension sheet is disposed on a same plane.

3. The power connector according to claim 2, wherein the pair of strip-shaped openings are vertically arranged side by side, and each of the conductive plates is disposed perpendicularly to the circuit board, and each of the conductive plates and the extension sheet are disposed on the same plane.

4. The power connector according to claim 3, wherein an amount of the strip-shaped openings is two pairs and an amount of the power terminal groups is two, two pairs of strip-shaped openings are arranged in an upper-lower manner, the extension sheet inserted in the pair of strip-shaped openings on upper side is an L-shaped piece, a shape of the L-shaped piece is defined with a gap, and the extension sheet inserted in the pair of strip-shaped openings on lower side is accommodated in the gap of the L-shaped piece.

5. The power connector according to claim 4, wherein the L-shaped piece comprises a bending section, a front section of the L-shaped piece and the conductive plate are arranged on the same plane, and a rear section of the L-shaped piece is arranged perpendicularly to the conductive plate and disposed on one side of the extension sheet on lower side.

6. The power connector according to claim 2, wherein the pair of strip-shaped openings are horizontally arranged in an upper-lower manner, each of the conductive plates is disposed parallelly with the circuit board, each of the conductive plates is arranged perpendicularly to the extension sheet, the extension sheet is bent to an L-shaped piece, the L-shaped piece comprises a bending section, a front section of the L-shaped piece and the conductive plate are arranged on the same plane, a rear section of the L-shaped piece is arranged perpendicularly to the conductive plate, and one L-shaped piece is accommodated below another L-shaped piece.

7. The power connector according to claim 1, further comprising a signal terminal group, wherein the insulating housing comprises a strip-shaped through hole aligned along the pair of strip-shaped openings, the signal terminal group comprises a plurality of signal terminals and an insulating sheet covering a middle section of the signal terminals, the insulating sheet is inserted in the strip-shaped through hole, one end of each of the signal terminals comprises a first pin disposed parallelly with each of the insertion pins and accommodated in the strip-shaped through hole, and another end of each of the signal terminals comprises a second pin disposed parallelly with each of the conductive pins and inserted in another portion of the conductive holes.

8. The power connector according to claim 1, further comprising two fixing plate, wherein the circuit board comprises two fixing holes, the insulating housing comprises two protrusions extended from two sides thereof and located at two sides of the pair of strip-shaped openings, each of the protrusions comprises a slot, the fixing plates are respectively inserted in the slots, and each of the fixing plates comprises a fixing pin exposed from the each protrusion and inserted in each fixing hole.

9. The power connector according to claim 8, wherein each of the slots is an H-shaped groove opened from one side wall of each protrusion; each of the fixing plates comprises an I-shaped piece, a cross-shaped piece, and a connecting piece integrally connected between the I-shaped piece and the cross-shaped piece; upper sections of each I-shaped piece, each connecting piece, and each cross-shaped piece are inserted in each H-shaped groove; each cross-shaped piece is engaged with each protrusion; and each fixing pin extends from a bottom end of each cross-shaped piece.

10. The power connector according to claim 8, wherein each of the slots is a T-shaped channel opened from a top of each protrusion, each of the fixing plates is a T-shaped piece, each of the T-shaped pieces is inserted in each T-shaped channel and engaged with each protrusion, and each of the fixing pins extends from a bottom end of each T-shaped piece.
